(19) United States
(12) Patent Application Publication
(10) Pub. No.: US 2024/0354474 A1
(43) Pub. Date: Oct. 24, 2024

(54) SYSTEM AND METHOD FOR MODELING NATURAL FRACTURE NETWORKS

(71) Applicants: SAUDI ARABIAN OIL COMPANY, Dhahran (SA); ARAMCO SERVICES COMPANY, Houston, TX (US)

(72) Inventors: Hussain ALBAHRANI, Qatif (SA); Farhan NASEER, Houston, TX (US); Weichang LI, Houston, TX (US)

(73) Assignees: SAUDI ARABIAN OIL COMPANY, Dhahran (SA); ARAMCO SERVICES COMPANY, Houston, TX (US)

(21) Appl. No.: 18/303,383

(22) Filed: Apr. 19, 2023

(51) Int. Cl. G06F 30/28

(52) U.S. Cl. CPC G06F 30/28

(57) ABSTRACT

In some examples, a system includes a stress field assessment engine, implemented by at least one processor, to determine stress distribution and yield state data based on a geomechanical model, and a natural fracture determination engine, implemented by the at least one processor, to generate a natural fracture network model based on the stress distribution and yield state data. The system may implement a method that includes generating a geomechanical model of a subsurface formation, where the geomechanical model includes a formation model and a wellbore model, simulating the geomechanical model to determine stress distributions and yield states in the subsurface formation, and generating a natural fracture network model using a machine learning technique on the stress distributions and yield states.

### FIELD OF THE DISCLOSURE

This disclosure relates generally to geomechanical modeling, and more particularly, to a system and method for modeling natural fracture networks in subsurface formations including a wellbore.

### BACKGROUND OF THE DISCLOSURE

A natural fracture, or a fault, is a separation in a formation that splits or divides material of the formation. The material of the formation may include rock formations, structures, or other geological features. The natural fracture may include one or more sections having different orientations within the formation (e.g., horizontal, vertical, slanted with respect to a surface of the formation). However, locations and configurations of natural fractures are often undetected and unknown within subsurface formations. While highly fractured subsurface formations may serve as hydrocarbon reservoirs, intersecting a natural fracture while drilling is problematic and potentially dangerous. Drilling fluids or muds, which facilitate drilling by stabilizing the subsurface formation, removing cuttings from the wellbore, and cooling and lubricating the drill bit, may be lost when the wellbore intersects the natural fracture. The lost drilling fluids, which contain different chemicals, increase operation costs and wellbore instability and lead to non-productive time while the drilling fluids are replaced.

### SUMMARY OF THE DISCLOSURE

Various details of the present disclosure are hereinafter summarized to provide a basic understanding. This summary is not an extensive overview of the disclosure and is neither intended to identify certain elements of the disclosure nor to delineate the scope thereof. Rather, the primary purpose of this summary is to present some concepts of the disclosure in a simplified form prior to the more detailed description that is presented hereinafter.

According to an embodiment consistent with the present disclosure, a system includes a stress field assessment engine, implemented by at least one processor, to determine stress distribution and yield state data based on a geomechanical model, and a natural fracture determination engine, implemented by the at least one processor, to generate a natural fracture network model based on the stress distribution and yield state data.

In another embodiment consistent with the present disclosure, a method includes generating a geomechanical model of a subsurface formation, where the geomechanical model includes a formation model and a wellbore model, simulating the geomechanical model to determine stress distributions and yield states in the subsurface formation, and generating a natural fracture network model using a machine learning technique on the stress distributions and yield states.

According to another embodiment consistent with the present disclosure, a non-transitory computer-readable medium storing computer-executable instructions, which, when executed by a processor, cause the processor to generate an initial geomechanical model that includes a formation model and a main wellbore model, simulate the initial geomechanical model to determine yield states and stress distributions in the formation model caused by drilling of the main wellbore model, and generate a natural fracture network model using a machine learning technique on the yield states and stress distributions.

Any combinations of the various embodiments and implementations disclosed herein can be used in a further embodiment, consistent with the disclosure. These and other aspects and features can be appreciated from the following description of certain embodiments presented herein in accordance with the disclosure and the accompanying drawings and claims.

### BRIEF DESCRIPTION OF THE DRAWINGS

FIG. 1 is a block diagram of a system for modeling natural fracture networks in a subsurface formation, in accordance with certain embodiments.

FIG. 2 is an example of a subsurface formation including a wellbore and a natural fracture, in accordance with certain embodiments.

FIG. 3 is an example of a stress field around a wellbore in a subsurface formation, in accordance with certain embodiments.

FIG. 4 is an example of a pressure response curve, in accordance with certain embodiments.

FIGS. 5A-5C are an example output including an image log and graphs of stress constraints for a wellbore in a subsurface formation, in accordance with certain embodiments.

FIG. 6 is an example of a graph illustrating stress distributions in a subsurface formation, in accordance with certain embodiments.

FIG. 7 is a flowchart of a method for modeling natural fracture networks in a subsurface formation, in accordance with certain embodiments.

FIG. 8 is a flowchart of a method for modeling natural fracture networks in a subsurface formation, in accordance with certain embodiments.

FIG. 9 is a flowchart of a method for modeling stress distributions in a subsurface formation, in accordance with certain embodiments.

FIG. 10 is a block diagram of a computer system that can be used to perform methods in accordance with certain embodiments.

### DETAILED DESCRIPTION

Embodiments of the present disclosure will now be described in detail with reference to the accompanying Figures. Like elements in the various figures may be denoted by like reference numerals for consistency. Further, in the following detailed description of embodiments of the present disclosure, numerous specific details are set forth in order to provide a more thorough understanding of the claimed subject matter. However, it will be apparent to one of ordinary skill in the art that the embodiments disclosed herein may be practiced without these specific details. In other instances, well-known features have not been described in detail to avoid unnecessarily complicating the description. Additionally, it will be apparent to one of ordinary skill in the art that the scale of the elements presented in the accompanying Figures may vary without departing from the scope of the present disclosure.

Embodiments of the present disclosure relate generally to geomechanical modeling, and more particularly, to a system and method for modeling natural fracture networks in subsurface formations including a wellbore. Geomechanical modeling, as used herein, refers to modeling a mechanical behavior of the subsurface formation and the wellbore. A geomechanical model accounts for physical properties of the subsurface formation, to include, but not limited to properties describing rock strength, rock elasticity, in situ stresses, and porosity of the subsurface formation. Existing modeling techniques for geomechanical modeling of a subsurface formation including a wellbore use known techniques of finite element analysis (FEA) that can be implemented using existing simulation software. The geomechanical modeling approach used by existing modeling software builds a geologic model of a subsurface formation that includes a wellbore and any known natural fractures, as indicated by low-resolution seismic data and sonic logs, and then determines in-situ stress distributions using the geologic model. However, the existing modeling software does not include modeling of unknown natural fractures, so drillers may not be able to plan around or seal the unknown natural fractures. Additionally, assumptions made by the drillers that wellbores drilled in a same subsurface formation (e.g., a same type of rock), having a like direction or trajectory, and using same or similar drilling tools, will have an almost identical drilling experience are invalid because the unknown natural fractures change (e.g., disturb) stress distributions in the subsurface formation, and drilling one or more wellbores further disturbs stress distributions in the subsurface formation. As described above, while exploring highly fractured subsurface formations results in discovery of hydrocarbon reservoirs, intersecting a natural fracture while drilling may result in lost drilling fluids (e.g., a loss circulation event) when the wellbore intersects the natural fracture. The lost drilling fluids increase operation costs and wellbore instability and lead to non-productive time while the drilling fluids are replaced.

Examples are described herein in which a stress field assessment engine uses wellbore data, physical properties of the subsurface formation, as well as other parameters described herein, to determine a geomechanical model of the subsurface formation. The term subsurface formation as used herein can include any type of earth layer. Thus, while examples are presented herein in which the subsurface formation is a rock layer, in other examples, the subsurface formation can be a different earth layer, or a combination of earth layers. The geomechanical model may include a wellbore model (representing a wellbore that is drilled into the subsurface formation) and a formation model (representing the subsurface formation in which the wellbore is drilled). Using the geomechanical model, the stress field assessment engine simulates stress distributions and yield states within the subsurface formation. A yield state, as used herein, occurs when a stress state reaches a combination of values, in a location within the formation, such that permanent (e.g., non-clastic, non-reversible, plastic) deformation occurs. A stress state, as used herein, is a quantification of a component of a stress tensor at a location within the formation. An output of the stress field assessment engine includes, but is not limited to, stress distribution and yield state data that is an input of a natural fracture determination engine. The natural fracture determination engine generates a natural fracture network model, or map, using a machine learning technique on the yield states and stress distributions data. The machine learning technique may use pattern recognition techniques, for example. The examples described herein for natural fracture network modeling enable prediction of loss circulation events when drilling a new wellbore in the subsurface formation. The examples presented herein retain the yield states and stress distributions from the wellbore and enable introduction of additional wellbores into the subsurface formation sequentially, in a manner that mimics actual drilling operations and that prevents loss circulation events. Prevention of loss circulation events increases safety of the drilling operations, decreases operation costs, and decreases an amount of time for field development.

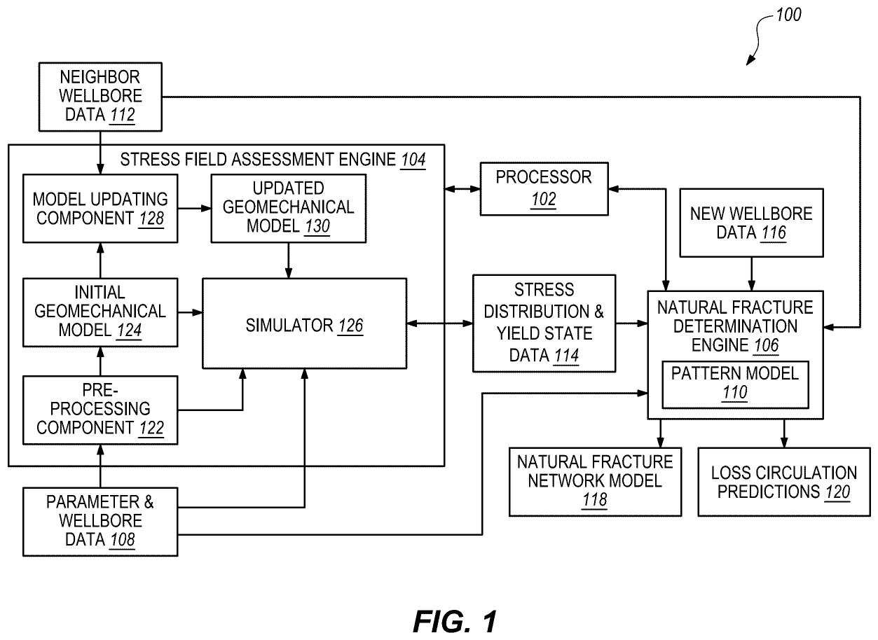

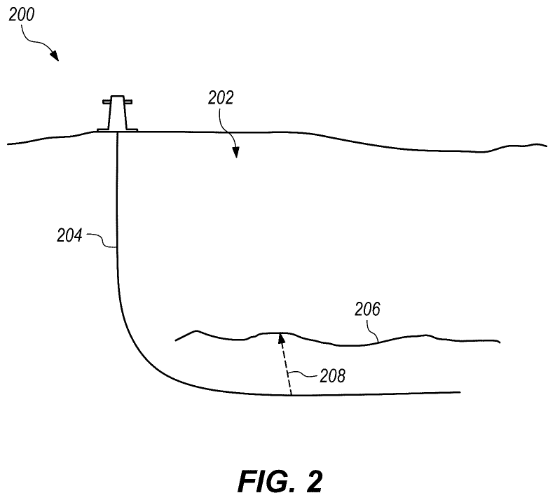

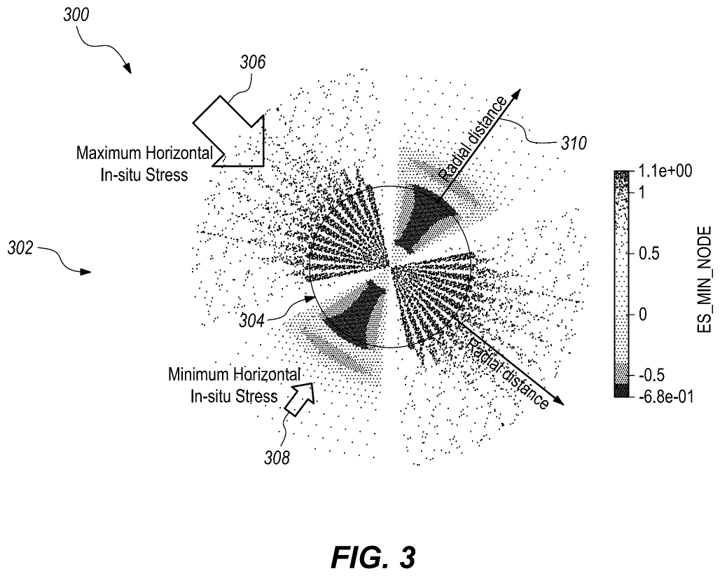

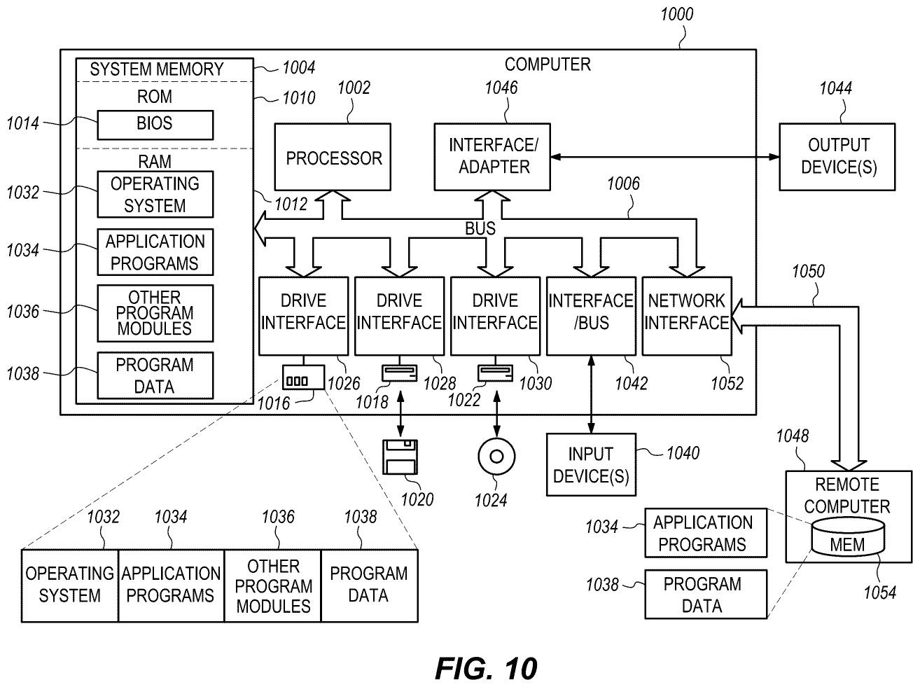

FIG. 1 is a block diagram of a system 100 for modeling natural fracture networks. The system 100 may be partially or fully implemented by the computer system 1000 shown in FIG. 10, for example. The system 100 enables data for a wellbore (e.g., a wellbore 204 as shown in FIG. 2, a wellbore 304 as shown in FIG. 3) drilled into a subsurface formation (e.g., a subsurface formation 202 as shown in FIG. 2, a subsurface formation 302 as shown in FIG. 3) to be translated into a subsurface model (e.g., initial geomechanical model 124) used by a stress field assessment engine 104 to determine stress distribution and yield state data 114 of the subsurface formation. The system 100 includes a natural fracture determination engine 106 that uses the stress distribution and yield state data 114 to determine a natural fracture network model 118 of the subsurface formation. In a non-limiting example, the natural fracture determination engine 106 enables predictions of loss circulation events (e.g., loss circulation predictions 120) associated with a proposed wellbore (e.g., new wellbore data 116) based on the stress distribution and yield state data 114.

In a non-limiting example, the system 100 includes the stress field assessment engine 104 that can be used to determine stress distribution and yield state data 114 based on a geomechanical model and the natural fracture determination engine 106 that can be used to generate the natural fracture network model 118 based on the stress distribution and yield state data 114. For a subsurface formation including a single wellbore, the geomechanical model may be the initial geomechanical model 124, for example. For a subsurface formation including multiple wellbores, the geomechanical model may be the updated geomechanical model 130, for example. One or more of the stress field assessment engine 104 or the natural fracture determination engine 106 can be implemented using hardware, software, or a combination thereof. For example, one or more of the stress field assessment engine 104 or the natural fracture determination engine 106 may be embodied as computer-executable instructions that define a software plugin or tool. The stress field assessment engine 104, the natural fracture determination engine 106, or a combination thereof, can be implemented as a part of software package used for modeling natural fracture networks, or as a stand-alone module that can be activated in response to the software package or a user (e.g., using an input device, as described by FIG. 10).

The stress field assessment engine 104 includes a pre-processing component 122 that can assign loads, assign heterogeneous material properties for the subsurface formation, and generate the initial geomechanical model 124. For example, the properties can include geologic (e.g., earth) in-situ stresses acting on a wellbore, a dimension, geometry and a placement of the wellbore within an in-situ stress field, and/or mechanical properties of solid components that form the wellbore. The solid components can include geologic formation rocks, a metal of a casing pipe, and/or a cement sheath attaching a pipe to the subsurface formation rock. The mechanical properties can include Young's Modulus, a Poisson's ratio, a yield point, stress-strain curve non-linearity coefficients, plasticity coefficients, and/or strain hardening or softening coefficients.

In a non-limiting example, the pre-processing component 122 can assign the loads and the properties based on parameter and wellbore data 108, which may include, but are not limited to, user-defined data or wellbore data, and thus provide load and property specifications for the initial geomechanical model 124. In some instances, the parameter and wellbore data 108 can define parameters for modeling the initial geomechanical model 124. The wellbore data is data associated with the wellbore drilled into the subsurface formation. The wellbore data may include, but is not limited to, data collected while drilling, to include data collected by wireline logging (WL) or logging while drilling (LWD) tools (e.g., collectively “logging tools”), or data from lab tests performed on core samples collected from the subsurface formation. For example, the wellbore data may include data associated with one or more of leak off test data, mini-fracturing test data, wireline acoustic and caliper logs. LWD acoustic logs, wireline image logs, LWD image logs, lab test data, drilling operations and engineering reports, wellbore trajectory and geo-spatial coordinates.

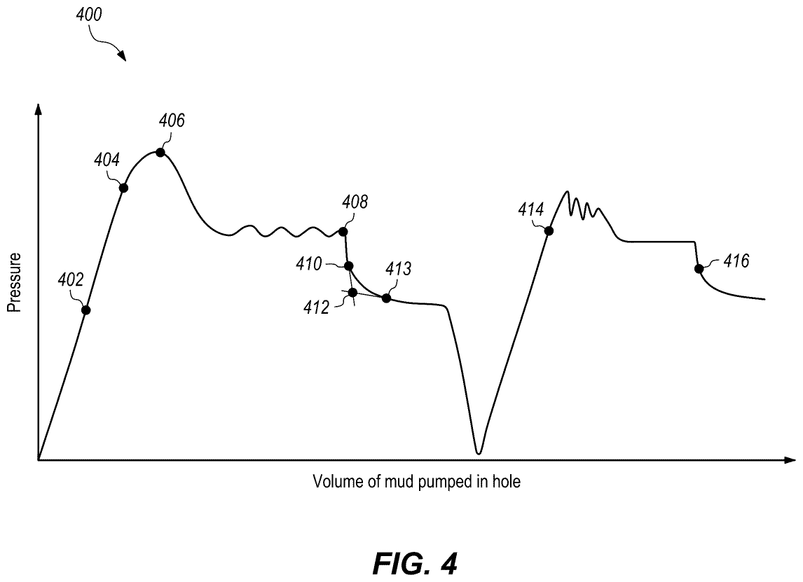

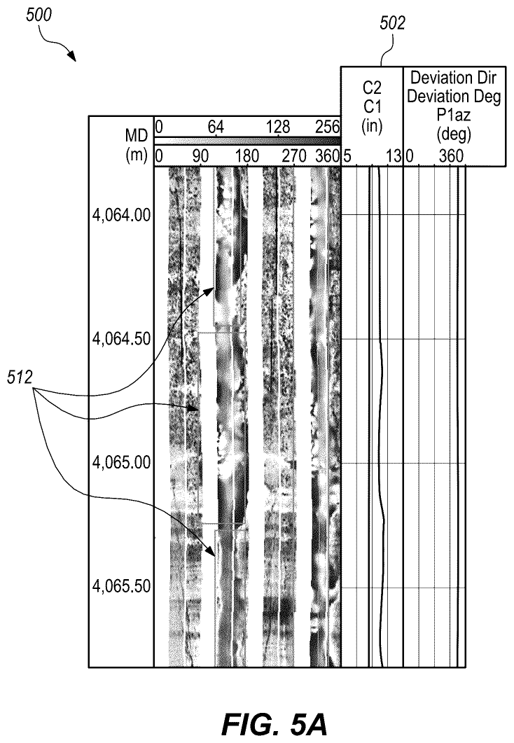

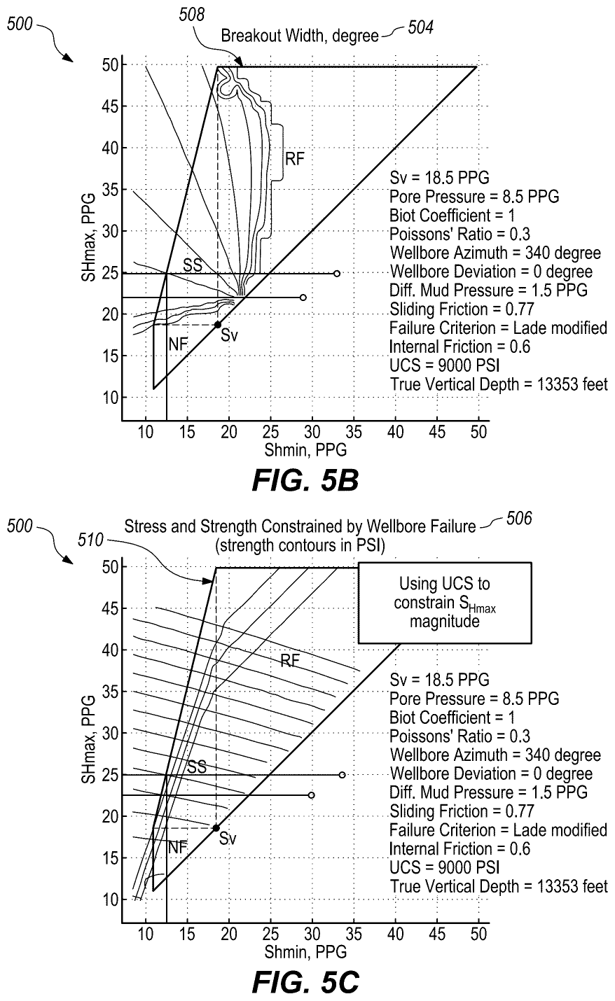

In a non-limiting example, the pre-processing component 122 can determine one or more of the loads or the properties using the parameter and wellbore data 108 as input. In some examples, the parameter and wellbore data 108 can be provided as an input file. In a non-limiting example, the pre-processing component 122 may determine the rock mechanical properties at different depths of the wellbore and at different radial distances from an axis of the wellbore (e.g., a radial 208 as shown in FIG. 2, a radial 310 as shown in FIG. 3) using one or more of lab test data, wireline acoustic and caliper logs, or LWD acoustic logs. In another non-limiting example, the pre-processing component 122 may determine a far field minimum horizontal stress value (e.g., a far field minimum horizontal stress 308, as shown in FIG. 3) using one or more of leak off test data or mini-fracturing test data. Both a leak off test and a mini-fracturing test include (1) pumping fluid into a wellbore at increasing pressure until a fracture is generated. (2) stopping the pumping, and (3) monitoring a pressure response at the surface. The pre-processing component 122 may use data of one or more of the leak off test or mini-fracturing test to determine a fracture closure pressure (FCP) graphically (e.g., FCP 412, as shown in FIG. 4), for example. The pre-processing component 122 may determine a far field maximum horizontal stress value (e.g., a far field minimum horizontal stress 308, as shown in FIG. 3) using one or more of wireline acoustic and caliper logs, LWD acoustic logs, wireline image logs, or LWD image logs, in a non-limiting example. For example, the pre-processing component 122 may determine the far field maximum horizontal stress value is within a range of values (e.g., values within stress polygon 508 or stress polygon 510, as shown in FIG. 5) using the one or more of wireline acoustic and caliper logs, LWD acoustic logs, wireline image logs, or LWD image logs (e.g., logs 502, as shown in FIG. 5). In another non-limiting example, using drilling operations and engineering reports, the pre-processing component 122 may determine whether lost circulation events occurred in a wellbore and whether the lost circulation was induced (e.g., caused by drilling operations) or due to a natural fracture. Using wellbore trajectory and geo-spatial coordinates, the pre-processing component 122 may determine influences of one or more neighbor wellbores on a main wellbore (e.g., observation wellbore), in a non-limiting example. A neighbor wellbore, as used herein, refers to an additional wellbore drilled within the subsurface formation including the main wellbore, where the additional wellbore may impact a stability of the main wellbore, either during drilling of the additional wellbore or during operation of the additional wellbore.

The initial geomechanical model 124 can model or represent the main wellbore in the subsurface formation. Thus, the initial geomechanical model 124 can be a combination of a main wellbore model (representing a wellbore that would be drilled or formed in a formation) and a formation model (representing the subsurface formation in which the wellbore would be drilled). The pre-processing component 122 can output the initial geomechanical model 124 that includes the main wellbore model, and in some instances other data for executing or running a simulation of the initial geomechanical model 124.

In some examples, the initial geomechanical model 124 is a mesh model. The initial geomechanical model 124 can be implemented as a three-dimensional (3D) model, and thus, in some instances is a 3D mesh model. For example, the initial geomechanical model 124 can be represented using a number of nodes. Each node of the initial geomechanical model 124 can represent where vertices and/or edges meet. The pre-processing component 122 can be used to model a geometry and characteristics of the subsurface formation and the main wellbore. The pre-processing component 122 in some instances can generate the initial geomechanical model 124 using a geometrical modeling engine. In some examples, the pre-processing component 122 can employ geomechanical modeling techniques to model elastic mechanical properties and physical laws of motion (e.g., a mass-spring methodology) to mimic or represent 3D deformation (e.g., rock deformation) in the formation model.

The stress field assessment engine 104 includes a simulator 126 that determines yield states and stress distributions radiating outward from a wall of a main wellbore with respect to a central axis of the main wellbore. In a non-limiting example, the simulator 126 can simulate stress distributions (e.g., stress concentrations, stress disturbances) that can result or be caused in the subsurface formation by the main wellbore based on the initial geomechanical model 124. In some examples, the simulator 126 employs finite element analysis (FEA) techniques to find (e.g., predict) the stress distributions in the subsurface formation from drilling or forming the main wellbore therein. For example, the simulator 126 can predict stress changes in the formation model during main wellbore formation simulation. Thus, the simulator 126 can simulate a creation of the main wellbore model in the formation model to represent formation of the main wellbore in the subsurface formation. Initially, during the main wellbore formation simulation, the formation model has an undisturbed stress field that is later (during the simulation) modified or changed due to forming the wellbore(s) therein. Thus, the simulator 126 can compute a disturbed stress field in the subsurface formation. In some examples, the simulator 126 can use or employ plasticity algorithms to model non-linear material behaviors of the formation model during the simulation in computing the disturbed stress field.

For example, the simulator 126 can be configured to use or apply discretization during the simulation using a minimization of a total potential energy according to expression (1):

$$u {\int }_{{V}^{e}} ( ( {B}^{T} ) D B ) d Ω = {\int }_{{V}^{e}} {N}^{T} F d Ω - {\int }_{{S}^{e}} {N}^{T} Td Γ , \qquad ( 1 )$$

where u is a displacement, B is a strain-displacement matrix and B^{T} is a transpose of the strain-displacement matrix, N^{T} is a transpose of a quadratic serendipity shape functions vector (e.g., which can be derived for a 20-nodes isoparametric brick element of the initial geomechanical model 124), D is a consistent tangent matrix (e.g., formulated based on mechanical properties of the subsurface formation), F is a body force, and T is a traction force.

In expression (1), the body force F and traction force T can represent or reflect in-situ stresses and mud weight loading on the main wellbore, and the displacement can indicate a deformation of a certain location within a solid body (e.g., a rock, cement, and/or metal pipe). If a certain fragment of the solid body has exhibited a displacement, this can indicate that this fragment has been deformed. In some examples, numerical simulation methods such as the FEM rely on fragmenting the solid body being examined into discrete elements. These elements can be in different shapes and configurations. In some examples, a 20-node brick element is used to perform fragmentation (or meshing) of a wellbore body. The 20-nodes in each fragmented (or meshed) element can function as a sensor. Through FEM calculations, the displacement can be assessed, and hence the deformation, at each node. The 20-node brick element can be selected because it allows for high resolution of displacement estimations while minimizing computation time.

The simulator 126 during the simulation can integrate expression (1) at an element volume V^{e} with respect to a volume variable Ω or at an element surface S^{e} with respect to an area variable I′. A matrix resulting from the integral in the expression to the left is known as the stiffness matrix K^{e}. The stiffness matrix can represent mechanical properties of the subsurface formation.

During the simulation, the simulator 126 can determine a strain hardening of the formation model to reflect or represent a plastic behavior of the subsurface formation. For example, the simulator 126 can employ a plastic flow rule for strain hardening to reflect the plastic behavior of the subsurface formation, which occurs beyond a yield point. The simulator 126 can determine a total strain (e.g., the strain hardening) for the subsurface formation as a function of a poro-elastic strain ε^{e} and a plastic strain ε^{P}. For example, a total strain can be an addition of a linear strain and a plastic strain. The linear strain can be determined from expression (1) by the simulator 126. The displacement u variable in expression (1) can be converted by the simulator 126 into a linear strain. The plastic strain component can then be determined by the simulation using expression (2). Thus, using the plastic flow rule, a flow direction can be perpendicular to a yield surface ψ according to expression (2):

$$Δ {ε}_{i j}^{p} = λ \frac{\partial ψ ( {σ}_{i j} )}{\partial {σ}_{i j}} , \qquad ( 2 )$$

where εᵢⱼ^{p} is a plastic strain tensor, σᵢⱼ is a stress tensor, and λ is a plastic strain multiplier.

The associative flow rule (e.g., the plastic flow rule) can be applied by the simulator 126 during the simulation by assuming that a plastic potential surface for the formation model is a same as the yield surface ψ. The simulator 126 during the simulation can also assume that the yield surface ψ expands without changing the flow direction. The simulator 126 uses a yield criterion for the yield surface ψ, for example, the Drucker-Prager criterion, where yielding will take place when a deviatoric stress tensor Sᵢⱼ and a mean stress σₘ satisfy the following expression:

$$ψ ( {σ}_{i j} ) = \sqrt{\frac{1}{2} {S}_{i j} {S}_{i j}} - {a}_{0} + {a}_{1} {σ}_{m} = 0 , \qquad ( 3 )$$

where constants a₀ and a₁ are determined experimentally as material properties and are used to correlate the Drucker-Prager criterion to a Mohr-Coulomb criterion.

During the simulation, the simulator 126 can calculate the scalar plastic strain EP from the plastic strain tensor according to the following expression:

$${ε}^{p} = \int \sqrt{\frac{2}{3} d {ε}_{i j}^{p} d {ε}_{i j}^{p}} \qquad ( 4 )$$

Accordingly, during the simulation, the simulator 126 can compute the stiffness matrix K^{e} and the displacement u by solving expression (1). The simulator 126 can compute or calculate residual forces corresponding to the body force F and traction force T. For example, the simulator 126 can use the residual forces to check for convergence and equilibrium with respect to expression (1) by subtracting a left-hand side from a right-hand side, where the left-hand side is the stiffness matrix K^{e} multiplied by displacement u and the right-hand side is the body force F and traction force T. The simulator 126 can determine that the equilibrium condition of expression (1) is satisfied if the value obtained from the subtraction of these two quantities is equal to zero, and thus expression (1) converges.

In some instances, the simulator 126 uses a tolerance value to check for convergence, for example, in scenarios in which it may not be achievable to satisfy the equilibrium condition of expression (1). The tolerance value can be set to be close to zero but not equal to zero. Once the residual forces are calculated by the simulator 126 and the simulator 126 determines that the residual forces are less than the tolerance value, convergence is said to be achieved; otherwise, the residual forces are carried to a next iteration. The above process is repeated for each separate load increment, where the load increments can be defined by the parameter and wellbore data 108.

In some examples, the simulator 126 can set or define a criterion for formation failure. For example, the simulator 126 can use baseline data (e.g., lab test data) to define a failure envelope for the formation model. The failure envelope can be defined at what is known as strength parameters for the formation model, and at certain limits of shear and normal stresses as specified by the baseline data (e.g., as observed in lab testing). Thus, the formation model can be used to suggest that formation failure can take place if stress states of the subsurface formation at the specified strength parameters is greater than the defined failure envelope.

In some examples, for each node of the initial geomechanical model 124, the simulator 126 can compute the stiffness matrix K^{e}. For example, the simulator 126 can compute the stiffness matrix K^{e} based on the strain-displacement matrix B, the transpose of the strain-displacement matrix B^{T} and the consistent tangent matrix D. The strain-displacement matrix B can contain derivatives of shape functions with respect to coordinate variables. The simulator 126 can compute a stress tensor σᵢⱼ for a respective node of the initial geomechanical model 124 based on the strain-displacement matrix B and the consistent tangent matrix D. The simulator 126 can compute a stress distributions that can include principal stress values for one or more nodes (e.g., point or locations) of the initial geomechanical model 124. For example, the simulator 126 can use Eigenvalues of the computed stress tensor σᵢⱼ as described herein for the one or more nodes. The stress distributions can be evaluated relative to failure criteria to determine whether the one or more nodes experienced a deformation failure during the simulation. The failure criteria may be included in the parameter and wellbore data 108, for example. As an example, the failure criteria can include a Mohr-Coulomb criterion, a Mogi criterion, a Drucker-Prager criterion, a Lade criterion, or a different type of failure criteria.

The failure criteria can be used by the simulator 126 during simulation to evaluate a stress states at each point (or node) against strength parameters assigned to said point to decide on a possibility of failure. For example, if the Mogi failure criterion is used by the simulator 126, the principle stresses calculated for the deformation model (e.g., (σ₁, σ₂, σ₃)) can be used to determine a value of an octahedral shear stress (τ). The simulator 126 can use a failure criteria function to compute for each respective point a failure criteria value based on the strength parameters assigned for a respective point and the calculated principle stress for the respective point. The simulator 126 can subtract the failure criteria value from the calculated octahedral shear stress and if a result is a positive value this can indicate that the point lies above the failure envelope, which means this point will be predicted to fail.

In some examples, the simulator 126 can compute stress field distributions around the main wellbore. For example, the simulator 126 can compute a displacement according the expression (1). The simulator 126 can convert the displacement into a strain value (e.g., based on the change in the solid body dimensions). The simulator 126 can convert the strain value into a stress value (e.g., based on a constitutive model for stress-strain). Thus, by determining the stress value at all locations (nodes) in a solid body, the simulator 126 can compute the stress field distribution.

In response to the simulation, the simulator 126 can output stress distribution and yield state data 114 characterizing the stress field from the simulation for the main wellbore model in the formation model. Thus, the stress distribution and yield state data 114 can characterize stress distributions in the formation model from only the creation of the main wellbore model in the formation model, which in some instances, is referred to herein as an undisturbed stress field. The stress distribution and yield state data 114 can be referred to as initial stress distribution and yield state data of the formation model. Accordingly, the simulator 126 can assess the initial stress distribution and the yield state data for the initial geomechanical model 124. The stress distribution and yield state data 114 can include stress values for nodes of the initial geomechanical model 124.

The stress field assessment engine 104 further includes a model updating component 128 that can update the initial geomechanical model 124 to include one or more additional wellbore models representative of neighbor wellbores that can be formed within the subsurface formation including the main wellbore. The model updating component 128 can update the geomechanical model based on neighbor wellbore data 112, which can identify parameters defining the one or more additional wellbore models, and in some instances parameters for simulating the one or more additional wellbore models. In some examples, the model updating component 128 can re-mesh the initial geomechanical model 124 to include the one or more additional wellbore models. The model updating component 128 can output the one or more additional wellbore models with the main wellbore model as an updated geomechanical model 130.

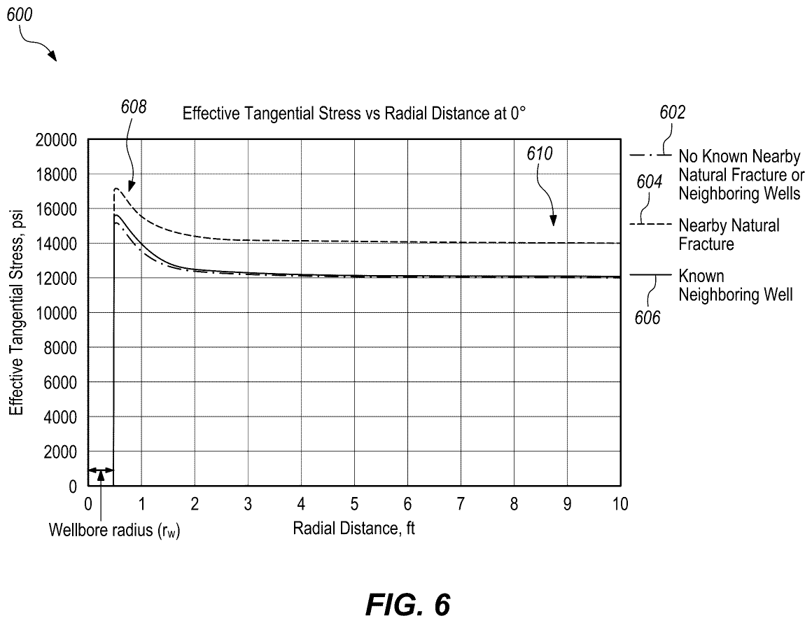

The simulator 126 can simulate stress distributions that can be caused in the formation model during creation of the one or more additional wellbore models therein based on the updated geomechanical model 130 and the initial stress distributions and yield states. For example, the simulator 126 can determine a stress distributions in both the main wellbore and one or more neighbor wellbores. The simulator 126 (or a different module) can be used to determine an outcome of an interaction between induced stresses from both the main wellbore and one or more neighbor wellbores according to the examples described herein. For example, the simulator 126 may determine stress distributions for one or more of a main wellbore (e.g., stress distribution plot 602 of FIG. 6), a natural fracture (e.g., stress distribution plot 604 of FIG. 6), or a neighbor wellbore (e.g., stress distribution plot 606 of FIG. 6). The simulator 126 can output updated stress distribution and yield state data 114 characterizing stress disturbances in the formation model from both the main wellbore model and the one or more additional wellbore models.

Accordingly, the stress field assessment engine 104 can be used to assess stress distributions and yield states extending from a central axis of a main wellbore. To ensure that the main wellbore influence is captured accurately, the stress field assessment engine 104 can update the geomechanical model with neighbor wellbore models while retaining the initial stress field calculations determined for the initial geomechanical model 124 and use the initial stress field calculations to compute updated stress field calculations for the subsurface formation using the updated geomechanical model 130. Furthermore, simulating the geomechanical model using a meshing technique with a 20-node brick element and according to the examples described herein can improve a computing speed at which the geomechanical model is simulated in comparison to other wellbore model simulation techniques that may be performed.

The natural fracture determination engine 106 receives the stress distribution and yield state data 114 and generates the natural fracture network model 118 using one or more machine learning techniques. In a non-limiting example, the natural fracture determination engine 106 uses one or more machine learning techniques employing a pattern recognition model 110 to determine whether the stress distribution and yield state data 114 includes patterns that are characteristic of a natural fracture. The one or more machine learning techniques may include one or more artificial neural networks (e.g., a convolutional neural network (CNN), a modular neural network (MNN), a recurrent neural network (RNN), a feedforward neural network, a radial basis function neural network, a Kohonen neural network, a long short term memory (LSTM) network), support vector machines (e.g., simple, kernel), random forest, bagging trees, K-nearest neighbor, or other machine learning techniques for classification, regression, or a combination thereof. In a non-limiting example, the natural fracture determination engine 106 determines which of the one or more machine learning techniques to use based on one or more sets of data of the parameter and wellbore data 108, one or more sets of data of the neighbor wellbore data 112, a type of the formation (e.g., clay, red bed, shale, soft limestone, unconsolidated sands, calcites, dolomites, hard shale, limestone, cherty limestone, hard shale, mudstones), a location of an oil field associated with the formation (e.g., land, sea), a size of the oil field (e.g., small, medium, large, major, giant, supergiant, megagiant), a number of wellbores of the formation, of the oil field, or a combination thereof. In a non-limiting example, the patterns that are characteristic of natural fractures may include one or more of elevated stress values, e.g., stress concentrations, or heightened states of compression, e.g., tension, at locations away from in proximity to a natural fracture, where the stress values, states of compression, or a combination thereof, dissipate as a distance between the natural fracture and an observation point (e.g., central axis of the main wellbore) increases. In a non-limiting example, the machine learning technique employing the pattern recognition model 110 differentiates between the patterns that are characteristic of natural fractures and patterns that are characteristic of naturally occurring heterogeneities that cause variations in the states of compression in a rock formation. By differentiating between the patterns that are characteristic of natural fractures and the patterns that are characteristic of naturally occurring heterogeneities that cause variations in the states of compression in a rock formation, the natural fracture determination engine 106 increases an accuracy for predicting presence of unknown natural fractures (e.g., natural fractures that have not been intersected by the main wellbore or one or more neighbor wellbores). In a non-limiting, the natural fracture determination engine 106 can determine distances of radials between a main wellbore, one or more neighbor wellbores, or a combination thereof, and a natural fracture and azimuth angles of the radials based on parameter and wellbore data 108, neighbor wellbore data 112, or a combination thereof. The parameter and wellbore data 108 includes trajectory and geo-spatial coordinates for the main wellbore and the neighbor wellbore data 112 includes trajectory and geo-spatial coordinates for the one or more neighbor wellbores, for example. Based on the trajectories, the geo-spatial coordinates, and the stress distribution and yield state data 114, the natural fracture determination engine 106 determines distances of radials between one or more natural fractures, the main wellbore, one or more neighbor wellbores, or a combination thereof, and azimuth angles of the radials, for example. In a non-limiting example, the stress distribution and yield state data 114 includes geo-spatial coordinates indicating one or more areas associated with one or more human-induced mechanical or chemical interactions, such as wellbore washouts, shale swelling, or the like. The simulator 126 may determine the geo-spatial coordinates using drilling operations and engineering reports of the parameter and wellbore data 108, for example. The natural fracture determination engine 106 generates the natural fracture network model 118 using one or more of the trajectories, geo-spatial coordinates, the distances of the radials, and the azimuth angles of the radials.

In a non-limiting example, the natural fracture determination engine 106 can determine loss circulation predictions 120 based on one or more of parameter and wellbore data 108, neighbor wellbore data 112, the stress distribution and yield state data 114, new wellbore data 116, the natural fracture network model 118, or a combination thereof. The new wellbore data 116 includes trajectory and geo-spatial coordinates for one or more new wellbores, for example. The natural fracture determination engine 106 receives the new wellbore data 116 and generates the loss circulation predictions 120 using the pattern recognition model 110 to determine whether drilling the new wellbore will result in no lost circulation events, lost circulations due to drilling induced fractures, or lost circulation events due to natural fractures.

In a non-limiting example, the natural fracture determination engine 106 includes a trainer module (not explicitly shown). Using one or more of the parameter and wellbore data 108, the neighbor wellbore data 112, the stress distribution and yield state data 114, the new wellbore data 116, the natural fracture network model 118, or the loss circulation predictions 120, the trainer module may update the pattern recognition model 110. By using the trainer module, the natural fracture determination engine 106 enables detection of differences between stress concentrations that are not visible to human detection. Additionally, each new wellbore exponentially increases a number of data points for analysis. The trainer module increases a speed and accuracy with which data is analyzed.

One or more of the stress field assessment engine 104 or the natural fracture determination engine 106 can be implemented using one or more modules. The one or more modules can be in software or hardware form, or a combination thereof. In some examples, one or more of the stress field assessment engine 104 or the natural fracture determination engine 106 can be implemented as computer-executable instructions for execution by a processor 102. The processor 102 may be a processor of any computing device, for example, a desktop computer, a server, a controller, a blade, a mobile phone, a tablet, a laptop, a personal digital assistant (PDA), and the like. By way of example, the memory storing the machine-readable instructions can be implemented, for example, as a non-transitory computer storage medium, such as volatile memory (e.g., random access memory), non-volatile memory (e.g., a hard disk drive, a solid-states drive, a flash memory, or the like), or a combination thereof. The processor 102 could be implemented, for example, as one or more processor cores. The memory can store machine-readable instructions (e.g., which can include the stress field assessment engine 104 or the natural fracture determination engine 106) that can be retrieved and executed by the processor 102. Additionally, the memory can store data (e.g., parameter and wellbore data 108, neighbor wellbore data 112, stress distribution and yield state data 114, new wellbore data 116, natural fracture network model 118, loss circulation predictions 120). Each of the processor 102 and the memory can be implemented on a similar or a different computing platform. The computing platform could be implemented in a computing cloud. In such a situation, features of the computing platform could be representative of a single instance of hardware or multiple instances of hardware executing across the multiple of instances (e.g., distributed) of hardware (e.g., computers, routers, memory, processors, or a combination thereof). Alternatively, the computing platform could be implemented on a single dedicated server or workstation.

FIG. 2 is an example of a multilateral wellbore 200 in a subsurface formation 202. In the example of FIG. 2, the subsurface formation 202 can include a rock formation, and in some instances other formations. The subsurface formation 202 includes the wellbore 204 and the natural fracture 206. Drilling experience shows that drilling of the main wellbore 204 changes, or disturbs, the stress field in the subsurface formation 202. Based on a distance of the radial 208 between the main wellbore 204 and the natural fracture 206, the presence of the natural fracture 206 changes the stress distribution caused by the drilling of the main wellbore 204.

In a non-limiting example, using techniques described herein, the changes of the stress distribution may be used to determine the distance of the radial 208 and an azimuth angle of the radial 208. Plotting the distances and azimuth angles determined using the changes of the stress distribution generates a map, or model, of the natural fracture 206.

FIG. 3 is an example of a stress field 300 around the wellbore 304 in the subsurface formation 302. The wellbore 304 may be the wellbore 204, as shown in FIG. 2, for example. Thus, reference can be made to the examples of FIGS. 1-2 in the example of FIG. 3. According to the examples described herein, the simulator 126 can compute or determine the stress field around the wellbore 304 in the formation model and thus an undisturbed stress field that has not been modified or changed by neighbor wellbores. Thus, the stress field in the example of FIG. 3 can be representative of an initial stress disturbance that would be caused by drilling of the wellbore 304 in the subsurface formation 302. A less shaded area in the example of FIG. 3 represents undisturbed stress values in the subsurface formation 302, while more shaded areas represent more disturbed stress values around the wellbore 304.

FIG. 4 is an example of a pressure response curve 400, in accordance with certain embodiments. The pressure response curve 400 may be generated using parameter and wellbore data. The parameter and wellbore data may be parameter and wellbore data 108, as described in FIG. 1. The parameter and wellbore data may include data of one or more of the leak off test or mini-fracturing test performed on a wellbore, for example. The wellbore may be the wellbore 204, as shown in FIG. 2, or the wellbore 304, as shown in FIG. 3. Thus, reference can be made to the examples of FIGS. 1-3 in the example of FIG. 4. The pressure response curve 400 is a graph of pressure responses at the surface during one or more of the leak off test or mini-fracturing test. A horizontal axis of the pressure response curve 400 represents a volume of fluid pumped into the wellbore and a vertical axis of the pressure response curve 400 represents a pressure response at the surface of the wellbore. The pressure response curve 400 includes multiple data points, e.g., formation integrity test 402, leak-off pressure (LOP) 404, formation breakdown pressure (FBP) 406, pumping cessation 408, fracture propagation 410, FCP 412, steady state 413, fracture re-opening pressure 414, second shut-in pressure 416. In a non-limiting example, one or more of values (e.g., pressure, volume of mud) associated with one or more of the formation integrity test 402, the leak-off pressure (LOP) 404, formation breakdown pressure (FBP) 406, the pumping cessation 408, the fracture propagation 410, FCP 412, the steady state 413, the fracture re-opening pressure 414, or the second shut-in pressure 416, are received as parameter and wellbore data by the stress field assessment engine (e.g., the stress field assessment engine 104, as described in FIG. 1).

In another non-limiting example, a pre-processing component (e.g., the pre-processing component 122, as described in FIG. 1) may use data of one or more of the leak off test or mini-fracturing test to determine the FCP 412 graphically using the pressure response curve 400. For example, the pre-processing component may determine that the formation integrity test 402 indicates a start of one or more of the leak off test or mini-fracturing test, may determine a pumped fluid compressibility, or a combination thereof. The pre-processing component may determine that the LOP 404 indicates an initiation of a tensile fracture in the wellbore wall. The pre-processing component may determine that the FBP 406 indicates a propagation and extension of a tensile fracture into the wellbore wall. The pre-processing component may determine pumping stops at pumping cessation 408 because a fracture occurs within the subsurface formation. The pre-processing component may determine that the fracture continues to propagate to fracture propagation 410. Using a double tangent method, the pre-processing component determines FCP 412. For example, the pre-processing component determines a first tangent to a first portion of a load-settlement curve, which has a starting point at pumping cessation 408, and a second tangent to a second portion of the load-settlement curve, which has a starting point when a curvature of the load-settlement curve reaches steady state 413. The pre-processing component determines an intersection of the first tangent and the second tangent is FCP 412. The pre-processing component may determine that the fracture re-opening pressure 414 indicates a pressure necessary to re-open the fracture in tension after the rock intrinsic tensile strength has been eliminated. The pre-processing component may determine that the second shut-in pressure 416 indicates a confirmation of the FCP determined in 412.

FIGS. 5A-5C are an example of an output 500 including an image log 502 and graphs 504, 506 of stress constraints for a wellbore in a subsurface formation, in accordance with certain embodiments. The image log 502 of FIG. 5A, graph 504 of FIG. 5B, and graph 506 of FIG. 5C may be generated using parameter and wellbore data. The parameter and wellbore data may be parameter and wellbore data 108, as described in FIG. 1. The parameter and wellbore data may include data of one or more of one or more of wireline acoustic and caliper logs, LWD acoustic logs, wireline image logs, or LWD image logs of a wellbore, for example. The wellbore may be the wellbore 204, as shown in FIG. 2, or the wellbore 304, as shown in FIG. 3. Thus, reference can be made to the examples of FIGS. 1-3 in the example of FIGS. 5A-5C. In a non-limiting example, the image log 502 of FIG. 5A is a resistivity-based image log. The graph 504 of FIG. 5B includes a stress polygon 508, and the graph 506 of FIG. 5C includes a stress polygon 510. In a non-limiting example, one or more of the graph 504 of FIG. 5B or the graph 506 of FIG. 5C includes other information determined using the parameter and wellbore data (e.g., Sv, pore pressure, Biot coefficient, Poisson's ratio, wellbore azimuth, wellbore deviation, diff. mud pressure, sliding friction, failure criterion, internal friction, unconfined compressive strength (UCS), true vertical depth). The stress polygon 508 of FIG. 5B and the stress polygon 510 of FIG. 5C include one or more of the far field maximum horizontal stress value, the far field minimum horizontal stress value, or the UCS expressed in pounds per gallon (ppg). In a non-limiting example, one or more of the image log 502 of FIG. 5A, the graph 504 of FIG. 5B, the graph 506 of FIG. 5C, the stress polygon 508 of FIG. 5B, the stress polygon 510 of FIG. 5C, the enlargement or breakout zones 512 of FIG. 5A, the far field maximum horizontal stress value, or the far field minimum horizontal stress value are received as parameter and wellbore data by the stress field assessment engine (e.g., the stress field assessment engine 104, as described in FIG. 1).

FIG. 6 is an example of a graph 600 illustrating stress distribution plots 602, 604, 606 in a subsurface formation, such as the subsurface formation 202 in the example of FIG. 2 or the subsurface formation 302 in the example of FIG. 3. Thus, reference can be made to the example of FIGS. 1-3 in the example of FIG. 6. The graph 600 characterizes tangential stress effects on a main wellbore (e.g., the wellbore 204 shown in FIG. 2) caused by a natural fracture (e.g., the natural fracture 206 shown in FIG. 2). A horizontal axis of the graph 600 represents a radial distance (in feet) from a central axis of the main wellbore and a vertical axis of the graph 600 represents an effective tangential stress around the central axis of the main wellbore (in pounds per square inch (PSI)). A stress distribution plot 602 illustrates the effective tangential stress caused by the main wellbore in the subsurface formation as the radial distance increases away from the central axis of the main wellbore. A stress distribution plot 604 illustrates the effective tangential stress caused by the main wellbore in conjunction with the natural fracture in the subsurface formation as the radial distance increases away from the central axis of the main wellbore. A stress distribution plot 606 illustrates the effective tangential stress caused by the main wellbore in conjunction with a neighbor wellbore in the subsurface formation as the radial distance increases away from the central axis of the main wellbore.

In a non-limiting example, an area 608 shows radii at which a deformation induces a stress concentration relative to a wellbore or a natural fracture. For example, as shown by the stress distribution plot 602, in a subsurface formation including only the main wellbore, a deformation induces a stress concentration of approximately 15000 psi at approximately 0.5 feet (ft) distance from a wall of the main wellbore relative to the central axis of the main wellbore. As shown by the stress distribution plot 604, in a subsurface formation including the main wellbore in proximity to a natural fracture, a deformation induces a stress concentration of approximately 17000 psi at approximately 0.5 feet (ft) distance from a wall of the main wellbore relative to the central axis of the main wellbore. As shown by the stress distribution plot 606, in a subsurface formation including the main wellbore, a neighbor wellbore, and a natural fracture, a deformation induces a stress concentration of approximately 15500 psi at approximately 0.5 feet (ft) distance from a wall of the main wellbore relative to the central axis of the main wellbore. As a distance between the wall of the main wellbore and the deformation increases, the stress concentration decreases until a far field stress value is reached.

In a non-limiting example, using techniques described herein, the differences between the stress distribution plots 602, 604, 606 may be used to determine distances and directions between the main wellbore and the natural fracture (e.g., distance and azimuth angle of radial 208, as shown in FIG. 2). Plotting the distances and azimuth angles determined using the changes of the stress distribution generates a map, or model, of the natural fracture.

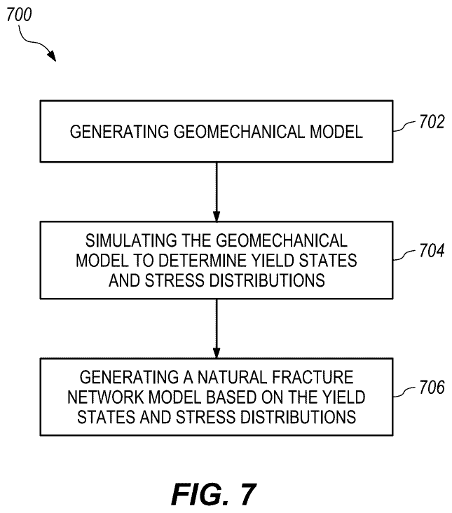

In view of the foregoing structural and functional features described above, an example method will be better appreciated with reference to FIGS. 7-9. While, for purposes of simplicity of explanation, the example methods of FIGS. 7-9 are shown and described as executing serially, it is to be understood and appreciated that the present examples are not limited by the illustrated order, as some actions could in other examples occur in different orders, multiple times and/or concurrently from that shown and described herein. Moreover, it is not necessary that all described actions be performed to implement the methods.

FIG. 7 is an example of a method 700 for modeling natural fracture networks in a subsurface formation (e.g., the subsurface formation 202 as shown in FIG. 2, the subsurface formation 302 as shown in FIG. 3). The method 700 can be implemented by the system 100, as shown in FIG. 1. Thus, reference can be made to examples of FIGS. 1-3 in the example of FIG. 7. At 702 of the method 700 a geomechanical model is generated. In a non-limiting example, the gcomechanical model includes a formation model and main wellbore model (e.g., generated by the pre-processing component 122, as shown in FIG. 1). In another non-limiting example, the geomechanical model includes an updated geomechanical model including the formation model, the main wellbore model, and one or more neighbor wellbore models (e.g., generated by the model updating component 128, as shown in FIG. 1). At 704 of the method 700, the geomechanical model is simulated (e.g., by the simulator 126, as shown in FIG. 1), to compute stress distributions (corresponding to the stress distribution and yield state data 114, as shown in FIG. 1) in the formation model caused during main wellbore model formation or neighbor wellbore formation. At 706, a natural fracture network model is generated based on the stress distributions (e.g., by the natural fracture determination engine 106, as shown in FIG. 1) to map one or more natural fractures in the subsurface formation.

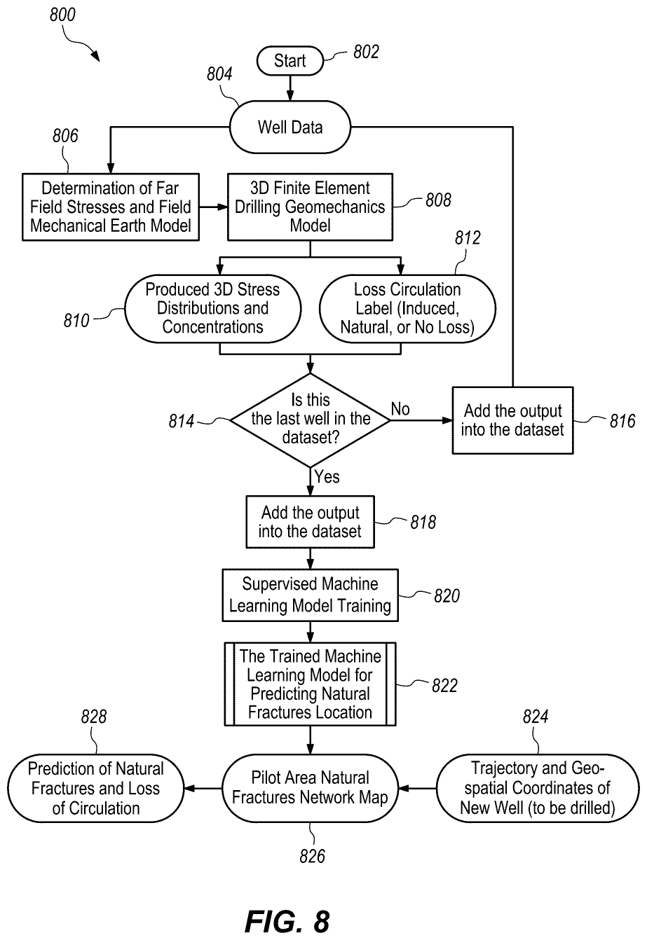

FIG. 8 is another example of a method 800 for modeling natural fracture networks in a subsurface formation (e.g., the subsurface formation 202 as shown in FIG. 2, the subsurface formation 302 as shown in FIG. 3). The method 800 can be implemented by the system 100, as shown in FIG. 1. Thus, reference can be made to examples of FIGS. 1-3 in the example of FIG. 8. The method 800 starts at block 802. The method 800 may start in response to receiving an input from a user, a system described herein, or another system communicatively coupled to the system described herein. In a non-limiting example, the method 800 starts at the block 802 in response to an indication that parameter and wellbore data 108 is available. The method 700 includes receiving the parameter and wellbore data 108 at a block 804. In a non-limiting example, the method 800 includes receiving the parameter and wellbore data 108 by retrieving the parameter and wellbore data 108 from a memory.

At block 806 of the method 800, one or more of the far field minimum horizontal stress value, the far field maximum horizontal stress value, a field mechanical earth model (e.g., model including mechanical properties of subsurface formation) are determined (e.g., by the pre-processing component 122, as shown in FIG. 1). At block 808 of the method 800, a geomechanical model is generated (e.g., by the pre-processing component 122, as shown in FIG. 1). The geomechanical model includes a formation model and a main wellbore model, for example. The geomechanical model may be an initial geomechanical model (e.g., the geomechanical model 124, as shown in FIG. 1) At block 810 of the method 800, stress distributions and concentrations are determined (e.g., by the simulator 126, as shown in FIG. 1). In a non-limiting example, the stress distributions and concentrations are 3D stress distributions and concentrations. At block 812 of the method 800, loss circulation events are labelled (e.g., by the pre-processing component 122 or the simulator 126, as shown in FIG. 1). In a non-limiting example, the method 800 includes storing one or more of the far field minimum horizontal stress value, the far field maximum horizontal stress value, the field mechanical earth model, the geomechanical model, or the stress distributions and concentrations to a dataset for training a machine learning model of a natural fracture determination engine (e.g., the natural fracture determination engine 106, as shown in FIG. 1) at block 816 and block 818.

The method 800 includes determining whether data is available for another wellbore of the subsurface formation at a block 814. In response to a determination that data is available for another wellbore, the method 800 includes returning to block 804 to receive data for an additional wellbore (e.g., neighbor wellbore data 112). In response to a determination that data is not available for another wellbore, the method 800 includes training the machine learning model (e.g., the pattern recognition model 110, as shown in FIG. 1) of the natural fracture determination engine at block 820. At block 822 of the method 800 a map of one or more natural fractures (e.g., the natural fracture network model 118) is generated (e.g., by the natural fracture determination engine 106, as shown in FIG. 1). At block 824 of the method 800 one or more of trajectory or geo-spatial coordinates of a new wellbore to be drilled (e.g., new wellbore data 116) is received (e.g., by the natural fracture determination engine 106, as shown in FIG. 1). Using the one or more of the trajectory or geo-spatial coordinates of the new wellbore, the method 800 includes determining a drilling plan for the new wellbore using the map of the one or more natural fractures at block 826. At block 828, the method 800 includes generating loss circulation predictions (e.g., loss circulation predictions 120, as shown in FIG. 1) using the drilling plan.

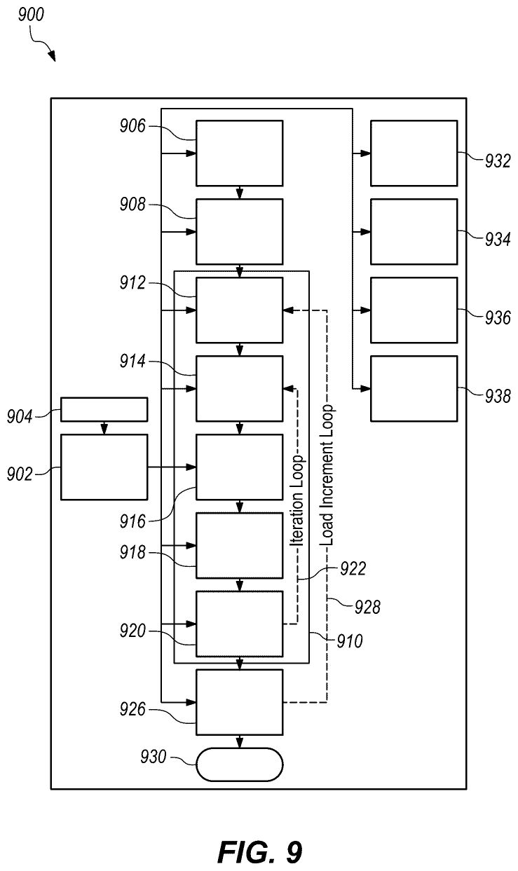

FIG. 9 is another example of a method 900 for modeling stress disturbances in formation (e.g., the subsurface formation 202, as shown in FIG. 2, the subsurface formation 302 as shown in FIG. 3). At least some of the method 900 can be implemented by the stress field assessment engine 104, as shown in FIG. 1. Thus, reference can be made to examples of FIGS. 1-3 in the example of FIG. 9. The method 900 can be start at 902 by initiating the stress field assessment engine 104 (e.g., executing the stress field assessment engine 104, as shown in FIG. 1). In some examples, at 902, dimension control data characterizing a dimension of a main wellbore and subsurface formation can be received by the stress field assessment engine 104 for generating corresponding main wellbore and formation models, respectively.

At 906, initial values can be set to zero. For example, input variables can be reset to a predefined value to avoid carrying values from a previous iteration or run. The input variables can include, for example, geologic (earth) in situ stresses acting on a wellbore, a dimension, geometry and a placement of the wellbore within an in situ stress field, and/or mechanical properties of solid components that form the wellbore. At 908, an input file (e.g., corresponding to the parameter and wellbore data 108, as shown in FIG. 1) can be received. The input file can specify load and property requirements for an initial geomechanical model. In some instances, at 908, an initial geomechanical model (e.g., the initial geomechanical model 124 as described with respect to FIG. 1) can be created that includes a main wellbore model and a formation model. In some instances, at 908, the initial geomechanical model can be loaded into the simulator 126, as shown in FIG. 1.

At 910, the initial geomechanical model can be simulated (e.g., by the simulator 126, as shown in FIG. 1) to compute stress distributions (or disturbances) that can result or be caused in the formation model by the main wellbore model based on the initial geomechanical model. In some instances, at 912, a first load increment of a number of load increments can be selected for the simulation of the initial geomechanical model (e.g., for one or more nodes of the model). The load increments can be specified by the input file, in some instances. At 914, a stiffness matrix representing mechanical properties of the subsurface formation and a displacement (e.g., as described herein) can be computed based on the first load increment. At 916, residual forces including a body force and a traction force can be calculated based on the first load increment.

At 918, the residual forces are evaluated relative to a tolerance value in a same or similar manner as described herein. At 920, a minimization of total energy expression (e.g., the expression (1), as described herein) is evaluated to determine whether this expression converged. The method 900 can proceed at 922 to step 914 in response to determining that the minimization of total energy expression did not converge, and the residual forces can be used in a next iteration (e.g., for other nodes). The iterations can be performed to ensure convergence. The convergence can be checked through estimating residual forces, for example, as described herein. For instance, the residual forces can be calculated to check for convergence and equilibrium by subtracting a left-hand side from a right-hand side in expression (1), where the left-hand side is a global stiffness matrix multiplied by a displacement, and the right-hand side is body and traction forces. The value obtained from the subtraction of these two quantities should be equal to zero if the equilibrium condition is fully satisfied. However, that is not always achievable, as described herein; therefore, a tolerance value can be set to check for convergence. The tolerance value can be set to be close but not equal to zero. Once the residual forces are calculated and found to be less than the set tolerance value, convergence can be said to be achieved; otherwise, the residual forces are carried to the next iteration.

In some examples, if the minimization of total energy expression did converge, at 926, data (e.g., a value of the displacement u) can be outputted indicating the convergence. The method 900 can proceed at step 928 to step 912 to select a second load increment of the load increments and the above process can be repeated. The method 900 can end at 930 after each load increment of the load increments has been evaluated.

In some examples, at 932, boundary conditions are provided as the displacement to define or identify fixed nodes of the initial geomechanical model. The boundary conditions can be used to define locations (nodes) within a wellbore body where displacements are already known. This can help reduce a number of unknown variables, so that a system of linear equations that will be produced from expression (1) can be solved (e.g., by the simulator 126, as shown in FIG. 1).

In some examples, at 934, deformation data relating to loading due to pressure and temperature on the subsurface formation can be considered by the simulator during stress field computations. For example, through empirical correlations, the simulator 126 can reflect an influence of temperature on stress distributions on the wellbore body

In some examples, at 936, a partial residual plot can be outputted based on the simulation carried out by the simulation during stress field computations that can graphically represent stress distributions in the formation model caused by the main wellbore model.

In some examples, at 938, a resolution index can be set for an integration solver of the simulator 126. Integrations, such as the ones described with respect to expression (1) are not solved analytically, but are solved using approximate methods by the simulator 126. By way of example, a method used here is a Gaussian quadrature. Because this method solves integrations at different resolutions (with respect to the integration function curve), this resolution can be set at step 938.

In view of the foregoing structural and functional description, those skilled in the art will appreciate that portions of the embodiments may be embodied as a method, data processing system, or computer program product. Accordingly, these portions of the present embodiments may take the form of an entirely hardware embodiment, an entirely software embodiment, or an embodiment combining software and hardware, such as shown and described with respect to the computer system of FIG. 10. Furthermore, portions of the embodiments may be a computer program product on a computer-usable storage medium having computer readable program code on the medium. Any non-transitory, tangible storage media possessing structure may be utilized including, but not limited to, static and dynamic storage devices, hard disks, optical storage devices, and magnetic storage devices, but excludes any medium that is not eligible for patent protection under 35 U.S.C. § 101 (such as a propagating electrical or electromagnetic signal per se). As an example and not by way of limitation, a computer-readable storage media may include a semiconductor-based circuit or device or other IC (such, as for example, a field-programmable gate array (FPGA) or an ASIC), a hard disk, an HDD, a hybrid hard drive (HHD), an optical disc, an optical disc drive (ODD), a magneto-optical disc, a magneto-optical drive, a floppy disk, a floppy disk drive (FDD), magnetic tape, a holographic storage medium, a solid-states drive (SSD), a RAM-drive, a SECURE DIGITAL card, a SECURE DIGITAL drive, or another suitable computer-readable storage medium or a combination of two or more of these, where appropriate. A computer-readable non-transitory storage medium may be volatile, nonvolatile, or a combination of volatile and non-volatile, where appropriate.

Certain embodiments have also been described herein with reference to block illustrations of methods, systems, and computer program products. It will be understood that blocks of the illustrations, and combinations of blocks in the illustrations, can be implemented by computer-executable instructions. These computer-executable instructions may be provided to one or more processor of a general purpose computer, special purpose computer, or other programmable data processing apparatus (or a combination of devices and circuits) to produce a machine, such that the instructions, which execute via the processor, implement the functions specified in the block or blocks.

These computer-executable instructions may also be stored in computer-readable memory that can direct a computer or other programmable data processing apparatus to function in a particular manner, such that the instructions stored in the computer-readable memory result in an article of manufacture including instructions which implement the function specified in the flowchart block or blocks. The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide steps for implementing the functions specified in the flowchart block or blocks.

In this regard, FIG. 10 illustrates one example of a computer system 1000 that can be employed to execute one or more embodiments of the present disclosure. Computer system 1000 can be implemented on one or more general purpose networked computer systems, embedded computer systems, routers, switches, server devices, client devices, various intermediate devices/nodes or standalone computer systems. Additionally, computer system 1000 can be implemented on various mobile clients such as, for example, a personal digital assistant (PDA), laptop computer, pager, and the like, provided it includes sufficient processing capabilities.

Computer system 1000 includes processing unit 1002, system memory 1004, and system bus 1006 that couples various system components, including the system memory 1004, to processing unit 1002. Dual microprocessors and other multi-processor architectures also can be used as processing unit 1002. System bus 1006 may be any of several types of bus structure including a memory bus or memory controller, a peripheral bus, and a local bus using any of a variety of bus architectures. System memory 1004 includes read only memory (ROM) 1010 and random access memory (RAM) 1012. A basic input/output system (BIOS) 1014 can reside in ROM 1010 containing the basic routines that help to transfer information among elements within computer system 1000.

Computer system 1000 can include a hard disk drive 1016, magnetic disk drive 1018, e.g., to read from or write to removable disk 1020, and an optical disk drive 1022, e.g., for reading CD-ROM disk 1024 or to read from or write to other optical media. Hard disk drive 1016, magnetic disk drive 1018, and optical disk drive 1022 are connected to system bus 1006 by a hard disk drive interface 1026, a magnetic disk drive interface 1028, and an optical drive interface 1030, respectively. The drives and associated computer-readable media provide nonvolatile storage of data, data structures, and computer-executable instructions for computer system 1000. Although the description of computer-readable media above refers to a hard disk, a removable magnetic disk and a CD, other types of media that are readable by a computer, such as magnetic cassettes, flash memory cards, digital video disks and the like, in a variety of forms, may also be used in the operating environment; further, any such media may contain computer-executable instructions for implementing one or more parts of embodiments shown and described herein.

A number of program modules may be stored in drives and RAM 1010, including operating system 1032, one or more application programs 1034, other program modules 1036, and program data 1038. In some examples, the application programs 1034 can include the stress field assessment engine 104 and the natural fracture determination engine 106 and the program data 1038 can include the parameter and wellbore data 108, the initial geomechanical model 124, the neighbor wellbore data 112, the updated geomechanical model 130, the stress distribution and yield state data 114, the new wellbore data 116, the pattern recognition model 110, the natural fracture network model 118, and the loss circulation predictions 120, as shown in FIG. 1. The application programs 1034 can include functions and methods programmed for modeling natural fracture networks according to the examples described herein.

A user may enter commands and information into computer system 1000 through one or more input devices 1040, such as a pointing device (e.g., a mouse, touch screen), keyboard, microphone, joystick, game pad, scanner, and the like. These and other input devices are often connected to processing unit 1002 through a corresponding port interface 1042 that is coupled to the system bus, but may be connected by other interfaces, such as a parallel port, serial port, or universal serial bus (USB). One or more output devices 1044 (e.g., display, a monitor, printer, projector, or other type of displaying device) is also connected to system bus 1006 via interface 1046, such as a video adapter.

Computer system 1000 may operate in a networked environment using logical connections to one or more remote computers, such as remote computer 1048. Remote computer 1048 may be a workstation, computer system, router, peer device, or other common network node, and typically includes many or all the elements described relative to computer system 1000. The logical connections, schematically indicated at 1050, can include a local area network (LAN) and a wide area network (WAN). When used in a LAN networking environment, computer system 1000 can be connected to the local network through a network interface or adapter 1052. When used in a WAN networking environment, computer system 1000 can include a modem, or can be connected to a communications server on the LAN. The modem, which may be internal or external, can be connected to system bus 1006 via an appropriate port interface. In a networked environment, application programs 1034 or program data 1038 depicted relative to computer system 1000, or portions thereof, may be stored in a remote memory storage device 1054.

Embodiments disclosed herein include:
A. A system including a stress field assessment engine, implemented by at least one processor, to determine stress distribution and yield state data based on a geomechanical model, and a natural fracture determination engine, implemented by the at least one processor, to generate a natural fracture network model based on the stress distribution and yield state data.
B. A method including generating a geomechanical model of a subsurface formation, where the geomechanical model includes a formation model and a wellbore model, simulating the geomechanical model to determine stress distributions and yield states in the subsurface formation, and generating a natural fracture network model using a machine learning technique on the stress distributions and yield states.
C. A non-transitory computer-readable medium storing computer-executable instructions, which, when executed by a processor, cause the processor to generate an initial geomechanical model that includes a formation model and a main wellbore model, simulate the initial geomechanical model to determine yield states and stress distributions in the formation model caused by drilling of the main wellbore model, and generate a natural fracture network model using a machine learning technique on the yield states and stress distributions.

Each of embodiments A through C may have one or more of the following additional elements in any combination: Element 1: where the geomechanical model is an initial geomechanical model, the wellbore model is a first wellbore model for a first wellbore, the stress distributions and yield states are initial stress distributions and yield states, and further including updating the initial geomechanical model to include an additional wellbore model for a second wellbore to generate an updated geomechanical model, and simulating the updated geomechanical model to determine updated stress distributions and yield states in the subsurface formation; Element 2: where generating the natural fracture network model uses the machine learning technique on the updated stress distributions and yield states; Element 3: further including predicting one or more loss circulation events occurring during drilling of a new wellbore based on the stress distributions and yield states and one or more parameters of the new wellbore; Element 4: where the machine learning technique is a pattern recognition technique that differentiates between stress concentrations associated with natural fractures in a wellbore model and naturally occurring heterogeneities that cause variations in states of compressions in the formation model; Element 5: where simulating the geomechanical model to determine the stress distributions in the subsurface formation includes computing a strain-displacement matrix based on a stiffness matrix and a displacement value, and computing a stress tensor for a respective node of the geomechanical model based on the strain-displacement matrix and a consistent tangent matrix; Element 6: where the stress distributions in the formation model include principal stress values for the respective node of the geomechanical model; Element 7: further including determining whether one or more nodes of the formation model experienced a deformation failure; Element 8: where a failure criteria of the deformation failure includes one of a Mohr-Coulomb criterion, a Mogi criterion, a Drucker-Prager criterion, and a Lade criterion; Element 9: where the stress field assessment engine is configured to generate the geomechanical model that includes a formation model and a wellbore model using a pre-processing component, and simulate the geomechanical model to determine the stress distribution and yield state data in a subsurface formation; Element 10: where the stress distribution and yield state data is initial stress distribution and yield state data, and where the stress field assessment engine is further configured to update the geomechanical model to include an additional wellbore model for a second wellbore to generate an updated geomechanical model using a model updating component, and simulate the updated geomechanical model to determine updated stress distributions and yield states in the formation model using the additional wellbore model and the initial stress distributions and yield states using the simulator component; Element 11: where the natural fracture determination engine is configured to use a pattern recognition technique to identify natural fractures of the natural fracture network by differentiating between stress concentrations associated with natural fractures in the wellbore model and naturally occurring heterogeneities that cause variations in states of compressions in the formation model; Element 12: where the natural fracture determination engine is further configured to predict one or more loss circulation events occurring during drilling of a new wellbore based on the yield state data, the stress distribution data, and one or more parameters of the new wellbore; Element 13: where the simulator component is configured to determine a strain-displacement matrix based on a stiffness matrix and a displacement value, and determine a stress tensor for a respective node of the initial wellbore model based on the strain-displacement matrix and a consistent tangent matrix; Element 14: where the processor is further operable to predict one or more loss circulation events occurring during drilling of a new wellbore based on the stress distributions and yield states and one or more parameters of the new wellbore; Element 15: where the machine learning technique uses a pattern recognition model that differentiates between stress concentrations associated with natural fractures in the main wellbore model and naturally occurring heterogeneities that cause variations in states of compressions in the formation model; Element 16: where the main wellbore model is a model for a first wellbore, and where the stress distributions and yield states are initial stress distributions and yield states, and where the processor is operable to update the initial geomechanical model to include an additional wellbore model for a second wellbore to generate an updated geomechanical model, and simulate the updated geomechanical model to determine updated stress distributions and yield states in the formation model using the additional wellbore model, the initial stress distributions and yield states; and Element 17: where the processor is further operable to generate an updated natural fracture network model using the machine learning technique on the updated stress distributions and yield states.

By way of non-limiting example, exemplary combinations applicable to A through C include: Element 1 with Element 2; Element 1 with Element 7; Element 1 with Element 8; Element 5 with Element 6; Element 7 with Element 8; Element 9 with Element 10; Element 9 with Element 11; Element 11 with Element 12; Element 11 with Element 13; and Element 16 with Element 17.

The terminology used herein is for the purpose of describing particular embodiments only and is not intended to be limiting of the invention. As used herein, for example, the singular forms “a,” “an,” and “the” are intended to include the plural forms as well, unless the context clearly indicates otherwise. It will be further understood that the terms “contains”, “containing”, “includes”, “including,” “comprises”, and/or “comprising,” and variations thereof, when used in this specification, specify the presence of stated features, integers, steps, operations, elements, and/or components, but do not preclude the presence or addition of one or more other features, integers, steps, operations, elements, components, and/or groups thereof. In addition, the use of ordinal numbers (e.g., first, second, third, etc.) is for distinction and not counting. For example, the use of “third” does not imply there must be a corresponding “first” or “second.” Also, as used herein, the terms “coupled” or “coupled to” or “connected” or “connected to” or “attached” or “attached to” may indicate establishing either a direct or indirect connection, and is not limited to either unless expressly referenced as such.

While the disclosure has described several exemplary embodiments, it will be understood by those skilled in the art that various changes can be made, and equivalents can be substituted for elements thereof, without departing from the spirit and scope of the invention. In addition, many modifications will be appreciated by those skilled in the art to adapt a particular instrument, situation, or material to embodiments of the disclosure without departing from the essential scope thereof. Therefore, it is intended that the invention not be limited to the particular embodiments disclosed, or to the best mode contemplated for carrying out this invention, but that the invention will include all embodiments falling within the scope of the appended claims. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

The invention claimed is:

1. A method, comprising:
generating a geomechanical model of a subsurface formation, wherein the geomechanical model includes a formation model and a wellbore model;
simulating the geomechanical model to determine stress distributions and yield states in the subsurface formation; and
generating a natural fracture network model using a machine learning technique on the stress distributions and yield states.

2. The method of claim 1, wherein the geomechanical model is an initial geomechanical model, the wellbore model is a first wellbore model for a first wellbore, and the stress distributions and yield states are initial stress distributions and yield states, and further comprising:
updating the initial geomechanical model to include an additional wellbore model for a second wellbore to generate an updated geomechanical model; and
simulating the updated geomechanical model to determine updated stress distributions and yield states in the subsurface formation.

3. The method of claim 2, wherein generating the natural fracture network model uses the machine learning technique on the updated stress distributions and yield states.

4. The method of claim 1, further comprising predicting one or more loss circulation events occurring during drilling of a new wellbore based on the stress distributions and yield states and one or more parameters of the new wellbore.

5. The method of claim 1, wherein the machine learning technique is a pattern recognition technique that differentiates between stress concentrations associated with natural fractures in the wellbore model and naturally occurring heterogeneities that cause variations in states of compressions in the formation model.

6. The method of claim 1, wherein simulating the geomechanical model to determine the stress distributions in the subsurface formation comprises:
computing a strain-displacement matrix based on a stiffness matrix and a displacement value; and
computing a stress tensor for a respective node of the geomechanical model based on the strain-displacement matrix and a consistent tangent matrix.

7. The method of claim 6, wherein the stress distributions in the formation model include principal stress values for the respective node of the geomechanical model.

8. The method of claim 2, further comprising determining whether one or more nodes of the formation model experienced a deformation failure.

9. The method of claim 8, wherein a failure criteria of the deformation failure includes one of a Mohr-Coulomb criterion, a Mogi criterion, a Drucker-Prager criterion, and a Lade criterion.

10. A system comprising:
a stress field assessment engine, implemented by at least one processor, to determine stress distribution and yield state data based on a geomechanical model; and
a natural fracture determination engine, implemented by the at least one processor, to generate a natural fracture network model based on the stress distribution and yield state data.

11. The system of claim 10, wherein the stress field assessment engine is configured to:
generate the geomechanical model that includes a formation model and a wellbore model using a pre-processing component; and
simulate the geomechanical model to determine the stress distribution and yield state data in a subsurface formation using a simulator component.

12. The system of claim 11, wherein the stress distribution and yield state data is initial stress distribution and yield state data, and wherein the stress field assessment engine is further configured to:
update the geomechanical model to include an additional wellbore model for a second wellbore to generate an updated geomechanical model using a model updating component; and
simulate the updated geomechanical model to determine updated stress distributions and yield states in the formation model using the additional wellbore model and the initial stress distributions and yield states using the simulator component.

13. The system of claim 11, wherein the natural fracture determination engine is configured to use a pattern recognition technique to identify natural fractures of the natural fracture network by differentiating between stress concentrations associated with natural fractures in the wellbore model and naturally occurring heterogeneities that cause variations in states of compressions in the formation model.

14. The system of claim 13, wherein the natural fracture determination engine is further configured to predict one or more loss circulation events occurring during drilling of a new wellbore based on the yield state data, the stress distribution data, and one or more parameters of the new wellbore.

15. The system of claim 13, wherein the simulator component is configured to:
determine a strain-displacement matrix based on a stiffness matrix and a displacement value; and
determine a stress tensor for a respective node of the initial wellbore model based on the strain-displacement matrix and a consistent tangent matrix.

16. A non-transitory computer-readable medium storing computer-executable instructions, which, when executed by a processor, cause the processor to:
generate an initial geomechanical model that includes a formation model and a main wellbore model;
simulate the initial geomechanical model to determine stress distributions and yield states in the formation model caused by drilling of the main wellbore model; and
generate a natural fracture network model using a machine learning technique on the stress distributions and yield states.

17. The non-transitory computer-readable medium of claim 16, wherein the processor is further operable to predict one or more loss circulation events occurring during drilling of a new wellbore based on the stress distributions and yield states and one or more parameters of the new wellbore.

18. The non-transitory computer-readable medium of claim 16, wherein the machine learning technique uses a pattern recognition model that differentiates between stress concentrations associated with natural fractures in the main wellbore model and naturally occurring heterogeneities that cause variations in states of compressions in the formation model.

19. The non-transitory computer-readable medium of claim 16, wherein the main wellbore model is a model for a first wellbore, and wherein the stress distributions and yield states are initial stress distributions and yield states, and wherein the processor is operable to:
update the initial geomechanical model to include an additional wellbore model for a second wellbore to generate an updated geomechanical model; and
simulate the updated geomechanical model to determine updated stress distributions and yield states in the formation model using the additional wellbore model and the initial stress distirbutions and yield states.

20. The non-transitory computer-readable medium of claim 19, wherein the processor is further operable to generate an updated natural fracture network model using the machine learning technique on the updated stress distributions and yield states.
